(19) United States
(12) Patent Application Publication
(10) Pub. No.: US 2006/0079103 A1
(43) Pub. Date: Apr. 13, 2006

(54) Compact connector for small devices

(76) Inventors: Chor Shan Cheng, Singapore (SG); Choon Kiat Lim, Singapore (SG); Niroot Jierapipatanakul, Singapore (SG); Djohni Chandra, Singapore (SG)

Correspondence Address: FISH & RICHARDSON PC, P.O. BOX 1022, MINNEAPOLIS, MN, 55440-1022, US

(21) Appl. No.: 11/141,745

(22) Filed: Jun. 1, 2005

(30) Foreign Application Priority Data
Oct. 13, 2004 (SG) 200406251-9

(51) Int. Cl. H05K 1/00

(52) U.S. Cl. 439/67

(57) ABSTRACT

A thin connector having generally opposing surfaces, one of which can be arranged facing a device, while the other presents conductive elements away from the device.

### FIELD OF THE INVENTION

The present invention relates generally to electronic devices, and more particularly to electrical connection between devices.

### BACKGROUND OF THE INVENTION

Consumer preference for convenience and mobility is forcing manufacturers to make numerous handheld electronic products increasingly smaller every year. The popularity of using such mobile personal electronic products to perform data-intensive activities, for example, capturing images, transmitting text messages, playing audio recordings, playing multimedia games, etc., is creating a growing need for affordable yet physically small devices with huge data storage capacities.

One way of meeting consumer needs in this area is to provide the consumer with a choice of using disc drives with his or her mobile personal electronic products. It is acknowledged that disc drive storage offers larger storage capacities at more affordable prices than other currently available storage options such as solid-state memories. However, in making storage suitable for use with mobile consumer products, the disc drive maker faces an infinitely bigger challenge than a solid-state memory maker because, in comparison, components of solid-state devices do not require as much physical space. A disc drive, on the other hand, is a system comprising moving and non-moving physical and electronic components designed to operate in tightly orchestrated harmony. Some minimal amount of real estate will always be required for movement and correct placement of the mechanical components of a disc drive. Therefore, shrinking the disc drive into a size suitable for use with mobile consumer products requires ingenuity in overcoming decades-old paradigms of disc drive design. Another problem is posed by the size of connectors traditionally used with disc drives. To fully minimize the size of any system using a disc drive, a better alternative to the traditional space-consuming connector is urgently needed.

The present invention provides a solution to this and other problems besides offering other benefits, as described below.

### SUMMARY OF THE INVENTION

Embodiments of the present invention provide solutions in the form of reducing the physical size of a connector suitable for releasably bridging circuits of devices.

According to one embodiment, there is provided a connector having generally opposing surfaces. When in use with a device, one of the surfaces can be arranged facing the device while the other surface presents conductive elements away from the device, the conductive elements being suitable for electrical connection with respective contacts of another connector of another piece of hardware. The connector is thin, that is, the opposing surfaces are separated by a relatively small extent of material as compared to the other linear dimensions of the connector. The connector may be made of flexible or stiff material or both. The connector can be in a folded or unfolded condition, depending on which is the desired configuration or assembly of the system using the device. Such a connector is suitable for use with different electronic devices, and advantageously adds very minimally to the overall dimensions of the devices or to systems using the devices.

These and various other advantages which characterize embodiments of the present invention will be apparent upon reading of the following detailed description and review of the associated drawings.

### BRIEF DESCRIPTION OF THE DRAWINGS

FIG. 1 is a schematic perspective of a device with a traditional connector.

FIG. 2 is a schematic perspective of a device with a connector according to one embodiment of the present invention.

FIG. 3-1 is an exploded schematic cross-sectional view of a system according to one embodiment of the present invention.

FIG. 3-2 is a schematic cross-sectional view of the system of FIG. 3-1 in assembly.

FIG. 4 is a schematic perspective of a system according to another embodiment of the invention in which the connector is in a folded condition.

FIG. 5 is a schematic perspective of another embodiment of the present invention.

FIG. 6 is a schematic perspective of a flap bent around two edges of a device; according to an embodiment of the present invention.

FIG. 7 is a schematic perspective showing portions of a connector of different stiffnesses according to another embodiment of the present invention.

FIG. 8 is a schematic cross-sectional view of a system according to yet another embodiment of the present invention.

FIG. 9 is a schematic cross-sectional view according to still another embodiment of the present invention, illustrating one possible arrangement of a flap with respect to a device.

FIG. 10 schematically depicts a perspective view of a miniature system according to one embodiment of the present invention.

### DETAILED DESCRIPTION

Embodiments of the present invention will be described below with reference to the appended drawings.

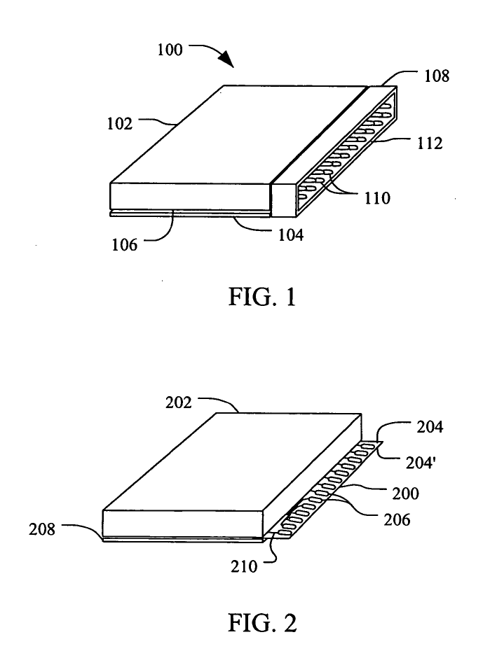

Taking a disc drive as just one example of a device that can be used with a host, the disc drive 100 shown in FIG. 1 includes a housing 102 with a printed circuit board assembly 104 attached to one external surface 106 of the housing. This printed circuit board assembly 104 carries electronic circuitry required for the operation of the disc drive 100, including: circuitry for the transmission of data from a host to the disc drive and vice versa, circuitry for drawing power from an external source for operation of the disc drive, etc. A connector 108 that is attached to the printed circuit board assembly 104 can be brought into releasable engagement with a complementary connector on the host's side (not shown). If the communication of data, instructions, and other electrical signals between the disc drive and its host follows a pre-determined interface protocol, there may be certain conventions or specifications governing the layout of the connections between these connectors. As shown in FIG. 1, the traditional male connector on the side of the disc drive could comprise a plurality of pins 110 supported by a connector housing 112. The connector housing 112 may be a stiff plastic or metal frame that holds the pins in the desired spaced-apart arrangement, while also acting as a guide for mating with the complementary connector that is attached to a host or other hardware. The pins 110 are generally elongated metal pieces each extending away from the device in a direction substantially perpendicularly to the housing 102 of the disc drive 100. A complementary female connector on the side of the host would generally be of a certain thickness to provide holes of a required depth for receiving the pins 110.

In contrast, embodiments of the present invention provide connections that would not add as much bulk to the device or system. Referring to FIG. 2, one embodiment of the present invention provides a relatively thin flap 200 attached to an electronic product 202 for providing electrical contact between the product and another electronic device (not shown). The flap 200 is configured so that one of its surfaces 204, 204′ can be arranged to rest against the product 202 while providing conductive contact zones 206 for electrical connection with the other electronic devices. In the example show, the flap 200 extends from the product 202. Optionally, the flap 200 may be an extension of a printed circuit board 208 that is part of the product 202, or the flap 200 may be soldered to the printed circuit board 208. The flap 200 may be in the form of an insulative material having a first face 204 and a second face 204′. Conductive paths or circuit traces 210 are borne in or on the insulative material. One or both faces 204, 204′ of the flap 200 may expose parts of the conductive paths 210 as zones 206. When the product 202 is seated in or otherwise coupled to another device, the flap 200 can be disposed between the product 202 and the other device, with the zones 206 of the conductive paths 210 coupled to conductive parts that lead to the circuitry of the other device. In this manner electrical connection between two pieces of hardware can be established. It can be seen that in comparison with a traditional interface or input/output connector (such as the example 108 shown in FIG. 1), this connector 200 with a flap-like form contributes significantly less bulk to the product 202 as a result of its relative thinness and its ability to lie substantially flat against surfaces of the product 202.

The conductive paths (such as 210) and the zones (such as 206) in or on the flap 200 may be formed by known methods such as etching or printing. It is conceived that the flap 200 may include conductive material laid out in a desired pattern on a non-conductive substrate. One end of each path 210 may be soldered or otherwise coupled to the respective parts of the circuitry of a device. At the other end of the path, the insulative material may be etched away or the conductive material exposed to form one or more zones 206. A zone 206 may have a width broader than that of the path 210 to facilitate contact with contacts of another device. The outermost surface of the zone 206 may be recessed from the face of the flap 200, raised relative to the surface 204, 204′, or in plane with a substrate 208, as it suits the intended mode of engagement with the contacts of the other device. For convenience only and without intent to be limiting, a zone (such as 206) of the conductive traces or circuit (such as 210) on the flap (such as 200) intended for forming releasable electrical engagement with an external circuit may be referred to in this document as “pad”. Also, for convenience only and without intent to be limiting, “contact” may refer to a conductive element of an external circuit, suitable for coming into electrical engagement with a pad.

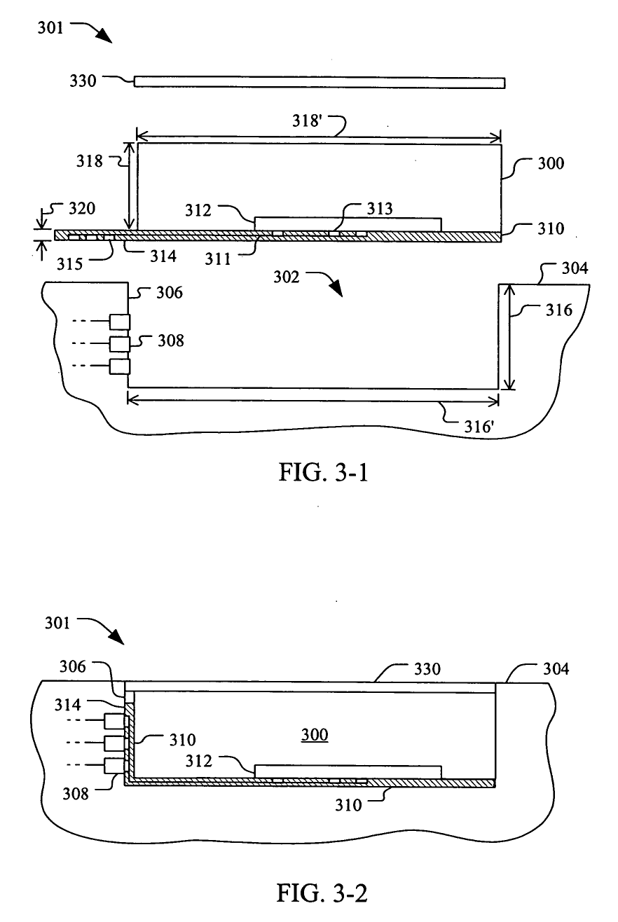

As provided by different embodiments of the present invention, electrical connection between a device and its host may be formed in various ways. Referring to FIG. 3-1, there is shown a system 301 that includes a device 300 sized to seat in a cavity 302 formed in the body of a host 304. On a cavity wall 306, the host 304 provides one or more contacts 308 that may lead to circuitry of the host 304. The device 300 has a flap 310 extending from the device 300, and bearing conductive paths 311 leading from circuitry 312 of the device 300. The conductive paths 311 may be connected to the circuitry 312 of the device 300 at their proximal ends 313 by soldering or other methods suitable for effecting permanent (that is, not easily releasable) engagement. The flap 310 may be an extension of a printed circuit assembly or it may be separate piece attached to a printed circuit assembly. The circuitry 312 may be located within or outside the housing of the device 300.

FIG. 3-2 shows the system in an assembled state when the device 300 has been slipped into the cavity 302 provided by the host 304. The cavity wall 306 interferes with the flap 310 so that the flap 310 is bent and tucked between the device 300 and the cavity wall 306. What is shown in FIG. 3-1 as a downward-facing side or surface 314 of the flap 310 faces towards the left in FIG. 3-2. One or more pads 315 located on that face 314 of the flap thus become operably coupled with respective contacts 308 along the cavity wall 306. The flap 310 serves as an electrical connector for the device 300 without requiring dimensions 316, 316′ of the cavity 302 to be significantly larger than the respective dimensions 318, 318′ of the device 300. It is envisaged that the cavity 302 may be larger only by a small allowance to provide for the thickness 320 of the flap 310 and for achieving the desired tightness of fit between the device 300 and the cavity 302.

Different embodiments of the present invention allow such a device to be used with the different standard connectors available today. The contacts on the host's side are therefore not elaborated here in detail as the host may continue to carry a conventional connector, such as a connector compatible for use with multimedia cards. This is another advantage made possible by various embodiments of present invention. In addition, embodiments of the present invention may be used with contacts that are designed to be stationary or to be biased towards the device. It can be seen from FIG. 3-2 that embodiments of the present invention are particularly suitable for use in systems where space constraint is a major concern. It follows that embodiments of the present invention can be well suited for use in systems where the electronic devices to be operably coupled have to be physically arranged next to each other with very little room for the traditional intervening connectors.

Another benefit offered by embodiments of the present invention is the compatibility with different possible methods of mounting devices onto hosts. A device with a flap of one embodiment of the present invention may be snapped into place in a molded cavity formed in the body of another electronic accessory or host, where the cavity is sized to receive the device fully or in part. For example, the device and the cavity may be sized for the device to be press-fitted into the cavity. Alternatively, the device may be slid into a groove sized to receive the device in whole or in part. The device may be retained in the cavity by a latching mechanism or by pushing forces from biased contacts. Referring to FIG. 3-2, a lid (such as 330) may be provided to close over the device in the cavity or another form of a retainer may be added to hold the device in the desired position. In yet another form, biased clips may be used to hold the device in the desired location with respect to the host. These and other variations may be implemented without hindrance arising from the implementation of embodiments of the present invention.

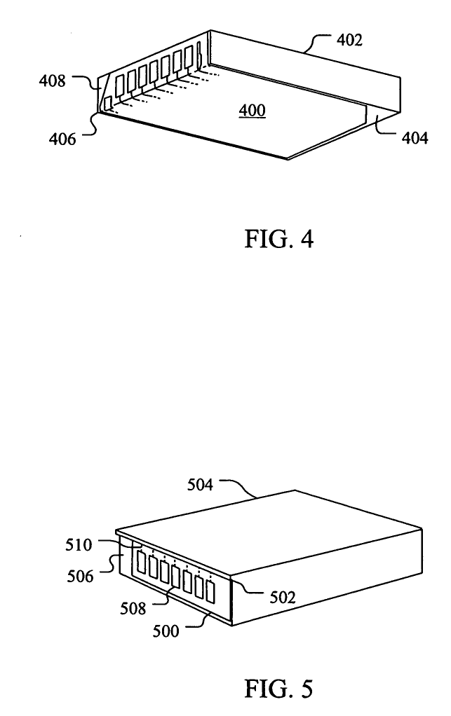

Another embodiment of the present invention is illustrated in FIG. 4. Here, a flap 400 is sufficiently flexible for it to follow the contours of the product 402. The flap 400 may extend from the product at one surface 404 of the product, and wrap around an edge 406 to end beside another surface 408 of the product. In other words, the flap 400 may be arranged next to or alongside one or more surfaces of the product 402. It is proposed that, optionally, the flap 400 may be held in position by adhesive or a retaining fixture so that it will not hang free from where it begins to extend.

Alternatively, as shown in FIG. 5, a flap 500 of another embodiment of the present invention may extend from an edge 502 of the device 504 in a plane substantially parallel to a surface 506 of the device. Optionally, the flap 500 does not run around any edge or corner of the device. Parts 508 of conductive paths or traces 510 leading from circuitry of the device 504 are positioned, facing away from the device, and ready for forming releasable electrical contact with an external circuit.

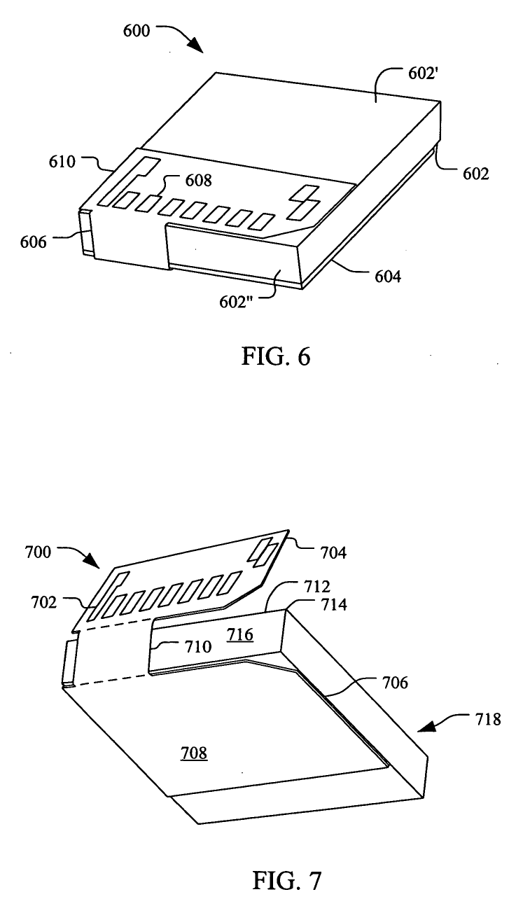

Referring now to FIG. 6 for another exemplary embodiment, there is shown a perspective view of a device 600 having opposing first and second surfaces 602, 602′. A printed circuit board assembly 604 with circuitry of the device 600 is mounted to the first surface 602 of the device. Extending from this printed circuit board assembly 604 is a flap 606 foldable around the device 600 to the second surface 602′ such that the flap 606 can rest adjacent to the second surface 602′ with pads 608 facing away from the device 600. When the device 600 is used with a host (not shown), the pad-bearing end 610 of the flap 606 can be sandwiched between the device 600 and the host. The pads can therefore be positioned to form electrical connection with an external device. Optionally, the free end 610 of the flap 606 may be made to stick close to the second surface 602′ of the device 600 even without the constraining effect of the host. For example, the flap 606 may be glued to one or more outer surfaces 602, 602′, 602″ of the device with adhesive. Optionally, one or more surfaces 602, 602′, 602″ of the device may be contoured to provide tighter fit around the flap 606. The connector 606 is shown in FIG. 6 in a folded condition although it will be understood that the connector can be used in an unfolded condition, depending on the relative position of the devices in assembly.

Optionally, a connector may be provided according to another embodiment of the present invention as shown in FIG. 7. A flap 700 may be be configured to have different stiffnesses at different parts. For example, extremeties or areas where the pads are located may be stiffer so that these parts can lie substantially in straight planes. This may be one way of enabling the pads 702 come into more effective yet releasable electrical engagement with respective contacts of an external connector or circuit. According to one embodiment, the flap 700 includes additional material 704 where higher stiffness is desired. The additional material 704 may be chosen to be one stiffer than the material used for making the rest of the flap 700. Another embodiment involves forming a flap 700 by overlaying one or more pieces of material 706 similar to that commonly used for the substrates of printed circuit boards with a flexible printed circuit cable 708. Part 710 of the flexible printed circuit cable 708 can be free of any stiffener or substrate so that the flap 700 is flexible at desired locations to be folded or bent around edges (such as 712), corners (such as 714), or sides (such as 716) of the device 718.

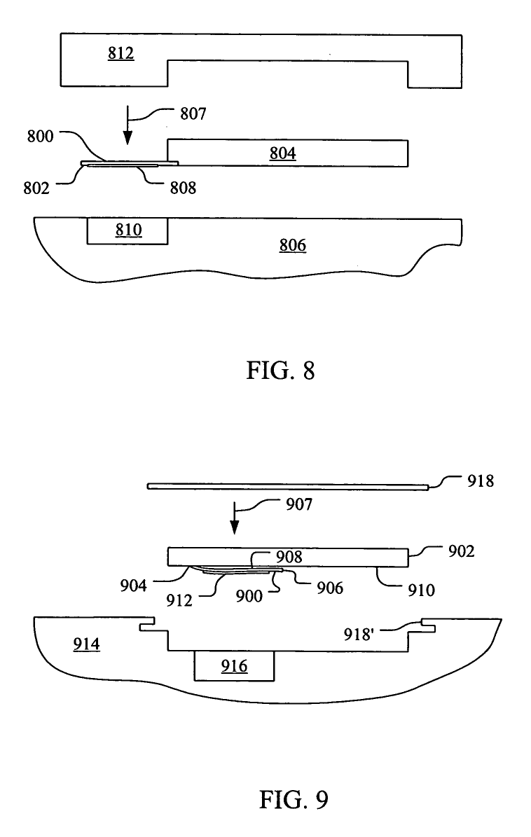

FIG. 8 illustrates yet another embodiment of the present invention. Although a flap 800 may be reoriented to present a pad 808 in another plane by bending, the pad-bearing end 802 of the flap is left hanging from the device 804 so that when the two electronic devices 804, 806 are coupled together, pressure is exerted in a desired direction 807 on the electrical connection between the pad 808 and the contact 810 to reinforce the electrical coupling. A cover component 812 may be added over the flap 800 or the device 804 to apply the desired pressure.

FIG. 9 shows another embodiment where a flap 900 extends from a device 902 to lie substantially parallel to a device surface 910. From the point or line of extension 904 to an extremity or edge 906 of the flap, the flap 900 may be arranged with one of its faces 908 against the device surface 910 of the device. The flap 900 may bear one or more pads 912 that are configured to face away from the device 902 or the device surface 910. In assembly with another electronic device 914, the pad 912 will form releasable electrical connection with one or more contacts 916, thus coupling the two devices 902, 914 for operation. Suitable pressure in a direction 907 angled with respect to a major surface 908 of the flap or to a surface 910 of the device may be applied to ensure physical contact and hence electrical connection, such as by use of a retainer, lid, cover, or like fixture (such as 918, 918′) with the assembly.

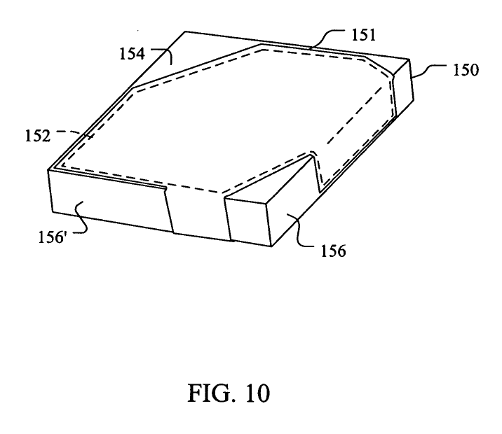

It is therefore clear that the present invention provides solutions suitable for various sizes of devices, including solutions that are especially useful in systems where the devices are physically small. Major advantages lie in the provision of comparable surface areas for electrical connection between two electronic devices even when the smaller device is physically not much larger than the required area for electrical contact. This is illustrated by the example of FIG. 10 where a device 150 uses a connector 151 that is but one embodiment of the present invention. The connector 151 can provide an area 152 for electrical contact as large as a major surface 154 of the device or more. By “major surface” one refers generally to the largest or one of the larger surfaces of the device. It will be understood that the connector 151 can also provide areas of electrical contact along the minor (or smaller) surfaces 156, 156′. This shows that embodiments of the present invention can be used even in the face of continued miniaturization of electronic devices, since the electrical contact can be provided without adding bulk to the overall system.

Advantageously, embodiments of the present invention can be used with a device that is sold as a retail product or as an application “embedded” in another product. In the latter, further advantages arise from allowing the manufacturer of the “embedding” product, such as a mobile phone, to incorporate an “embedded” product, such as a disc drive, without requiring changes or modifications to the connector in the “embedding” product. Accordingly, this may provide cost savings opportunities to manufacturers of the “embedding” product, which may then translate into more affordable products for the consumers.

Another benefit that can be derived from the present invention is that there is now no necessity to factor in precious real estate for an input-output connector on the side of the device. The overall size and weight of the device can be as small and as light as the other operational and structural components of the device can be miniaturized. In other words, compared with a traditional connection system, it can be seen that a system incorporating an embodiment of the present invention can help make a system overall more compact.

It will be understood that the foregoing description of the various embodiments is illustrative only, and that changes can be made by one skilled in the art without departing from the scope of the present invention.

What is claimed is:

1. A connector for use with a device, the connector comprising:
a first surface;
a conductive element leading to a distal end on the first surface; and
a second surface generally opposing the first surface, in which the second surface is disposable next to the device.

2. The connector of claim 1, in which the distal end is configured for releasable electrical coupling with an external electrical contact.

3. The connector of claim 1, in which the distal end of the conductive element comprises a pad exposed for external electrical contact.

4. The connector of claim 1, in which the conductive element further comprises a proximal end solderable to a circuit of the device.

5. The connector of claim 1, in which the second surface is disposable substantially parallel to a surface of the device.

6. The connector of claim 5, in which the surface of the device is a major surface.

7. The connector of claim 5, in which the surface of the device is a minor surface.

8. The connector of claim 1, in which the first surface and the second surface are separated by a narrow extent of material.

9. The connector of claim 1, in which the second surface is disposable next to at least two surfaces of the device.

10. The connector of claim 1, in which the connector is characterized by a stiffness sufficiently low for the connector to be bent around at least one edge of the device.

11. A system comprising:
a first device having at least one external surface;
a connector having:
a first surface;
a conductive element leading to a distal end on the first surface; and
a second surface generally opposing the first surface, in which the second surface is disposable next to the external surface.

12. The system of claim 11, in which the second surface is disposable substantially parallel to the external surface.

13. The system of claim 12 in which the external surface is a major surface.

14. The system of claim 12 in which the external surface is a minor surface.

15. The system of claim 11, in which the first surface and the second surface are separated by an extent of material that is thin relative to a thickness of the first device.

16. The system of claim 11, in which the second surface is disposable next to at least two external surfaces of the first device.

17. The system of claim 11, in which the connector is bendable around at least one edge of the first device.

18. The system of claim 11, in which the conductive element is engageable in electrical connection with a circuit of a second device.

19. The system of claim 18, in which the distal end of the conductive element comprises an area exposed for electrical connection with the circuit of the second device.

20. The system of claim 11, in which the conductive element further comprises a proximal end solderable to a circuit of the first device.

21. The system of claim 11 further comprising a second device, in which the connector is disposable between the first device and the second device when in assembly.

22. The system of claim 21, in which electrical connection formed between the connector and the second device is releasable.

23. The system of claim 21 in which, in assembly, the first device is biased towards the second device with the connector disposed therebetween.

24. The system of claim 11 in which the first device is a storage device.

25. The system of claim 24 in which the first device is a disc drive.
